(19) United States
(12) Patent Application Publication
(10) Pub. No.: US 2010/0293425 A1
(43) Pub. Date: Nov. 18, 2010

(54) PARAMETRIC SCAN REGISTER, DIGITAL CIRCUIT AND METHOD FOR TESTING A DIGITAL CIRCUIT USING SUCH REGISTER

(75) Inventors: Olivier Heron, Bullion (FR); Yannick Bonhomme, La Val Saint Germain (FR)

Correspondence Address: DARBY & DARBY P.C., P.O. BOX 770, Church Street Station, New York, NY, 10008-0770, US

(73) Assignee: COMMISSARIAT AL'ENERGIE ATOMIQUE, Paris (FR)

(21) Appl. No.: 12/444,443

(22) PCT Filed: Oct. 5, 2007
(86) PCT No.: PCT/EP07/60591

§ 371 Date: Jul. 22, 2009

(30) Foreign Application Priority Data
Oct. 6, 2006 (FR) 06/08798

(51) Int. Cl. G01R 31/3177; G06F 11/25

(52) U.S. Cl. 714/731; 714/E11.155

(57) ABSTRACT

The present invention relates to a parametric scan register and a method of testing a digital circuit with the aid of such a register. The parametric scan register includes a memory cell having at least one data input, able to receive a test datum, and transferring to its output a representative signal indicative of the test datum by use of a synchronization signal. It furthermore includes a parametric test block one input of which is linked to the output (s) of the cell, the output signal of the cell being transferred at the output of the parametric test block through an internal module, this internal module operating according to modes able to modify the output signal of the cell. Embodiments of the invention apply to the testing of integrated circuits with high integration density, for example in the field of nanotechnologies.

The present invention relates to a parametric scan register comprising at least one parametric scan cell. It also relates to a method of testing a digital circuit with the aid of such a register. It relates finally to a digital circuit equipped with at least one parametric scan register or parametric scan cell. The invention applies notably for the testing of integrated circuits with high integration density, for example in the field of nanotechnologies.

If the case of digital integrated circuits (ICs) is considered, an objective of the tests is to reject ICs that have failed during a manufacturing flow, that is to say ICs that do not comply with the desired specifications. The expression digital IC is understood to mean an integrated circuit carrying out a specific function, for example a circuit of the ASIC (Application Specific Integrated Circuit) type. It is known to apply stimuli or test vectors to the inputs of an IC and subsequently to analyze the responses. If the responses observed are comparable with those expected then the test concludes a success, otherwise the IC is considered to be defective.

An exhaustive test makes it possible to detect the maximum number of defects. This type of test is nevertheless very expensive in terms of time, since the number of vectors increases as a power of 2 with the number of inputs. Test schemes have been proposed in the literature with the objective of minimizing the test time per IC. These schemes can be classed into two categories according to the approach adopted: functional test or structural test. In the first approach, the test vectors are justified by the digital function of the IC to be tested. In the structural test approach, the aim is no longer to verify the function of the IC but its structure. For this purpose the test vectors are generated on the basis of models representing faulty behaviors of the structure of the IC.

The models used in the structural test are called faults and represent failure mechanisms due to physical defects. For example, the stuck-at-0/1 fault model represents a defect such as a straightforward short-circuit of a line of the circuit with an equipotential at 0, or at 1, as described notably in the work by C. Landrault “Test de Circuits et de Systèmes Intégrés” [Testing of Integrated Circuits and Systems], Chap. 2, pp. 60-62, Published by Lavoisier, 2004. Other models have been proposed in order to cover the maximum number of physical defects such as the delay fault model for taking account of “delays”, notably described in the article by M. A. Breuer “The Effects of Races, Delays and Delay Faults on Test Generation”, IEEE Trans. On Computers, Vol. 23, pp. 1078-1092, October 1974. Although these tests make it possible to detect a wide gamut of physical defects during the manufacturing phase, advances in the miniaturization of ICs induce other defects which are not detected by these tests.

Other test schemes are also known such as the current test described notably in the aforesaid work by C. Landrault in chapter 5, pp. 148-153. This test consists in detecting an overconsumption of current by the circuit in a known state. This approach is conceivable if the dynamic consumption remains sufficiently greater than the static currents of a transistor. Joint use of these testing schemes makes it possible to detect the majority of physical defects in ICs in submicron technology.

With the increase in the number of functions integrated into one and the same silicon substrate, the present test techniques cannot guarantee complete coverage of defects in an acceptable time. In order to limit the complexity of the production tests, techniques for designing ICs with a view to these tests have been proposed in the literature. These techniques make it possible to improve the testability of ICs. The insertion of so-called Scan chains is a commonly used solution. It makes it possible notably to facilitate the testing of ICs by improving their control and their observability as shown in the work by C. Landrault in chapter 7, pp. 200-210 or the article by M. William and J. Angel “Enhancing testability of LSI Circuits via Test Points and Additional Logic”, IEEE Trans. On Computers, Vol. C-22, No. 1, January 1973. The principle of the insertion of Scan chains consists in modifying the structure of the memory registers of an IC into a Scan register. This register possesses two operating modes: test and normal. In the test mode, the Scan registers offer serial access. The input and the output of the chain allow respectively the loading and the unloading in series of test vectors and responses, via the test inputs and outputs. In the normal mode, the operation of the register is preserved, rendering the insertion of Scan chains transparent in respect of the operation of the IC.

However, the application of these conventional test techniques does not make it possible to guarantee that the circuit will be free of failure during its use. This phenomenon is accentuated with the use of nanotechnologies. Specifically, the number of dynamic failures increases with the reduction in the sizes of the transistors. This type of failure may be due to induced defects, that is to say failure mechanisms resulting from phenomena of crosstalk between internal components of the circuit or with the outside environment. It may also be due to rapid wear of the IC which results in the appearance of physical phenomena, for example electromigration or else corrosion of the oxide.

Thus, though an increase in the integration density of digital ICs makes it possible to insert an increasing number of functions into them, on the other hand a large rise is noted in the probability of permanent defects, or manufacturing defects, and transient defects, manifesting during operation. Such defects can induce failures that may be unacceptable in certain fields of application. A test, in all its variants such as described above, makes it possible to improve the reliability of ICs.

However, with the arrival of “nanotechnologies”, new technological problems arise regarding the reliability of ICs. Among the main problems may be cited:
the complexity of the test which has a tendency to increase in a quasi-exponential manner with the number of logic gates or transistors of the ICs, rendering IC development costs all the more significant;
the reduction in the size of the manufacture methods which inevitably involves a decrease in the robustness of the technology used, which results notably in the manifesting of new defects in the structure which are unable to be detected via the present test techniques;
the rather more analog behavior of ICs in nanometer technology which shows that certain failure mechanisms, previously masked in the submicron technologies, become predominant, in particular the transient phenomena and the noise generated by the outside environment or the structure itself become predominant during the operation of an IC, normal or under test.

Subsequently in the document, the term cell is understood to mean a unit memory element of an IC. A memory cell typically comprises a flip-flop and structural elements.

A register is a logic operator composed of n cells each exhibiting a logic output, furnished with global controls, for disabling or resetting to zero notably. It is intended to momentarily retain in memory a binary number of n digits. A register is composed of at least two memory cells which may or may not be chained together.

A scan chain is constructed by placing the cells in a register in series, solely for the test.

A scan register (SR) is composed of several scan cells. A parametric scan register (PSR) comprises several scan cells, including at least one parametric scan cell (PSC).

An IC comprises at least one memory cell and generally at least one register of several cells.

One aim of the invention is notably to respond to these problems. For this purpose, one subject of the invention is a scan register comprising a parametric scan memory cell having at least one data input d, able to receive a test datum e_scan, and transferring to its output s a representative signal indicative of the input datum by means of a synchronization signal, the scan cell furthermore comprises a parametric test block one input of which is linked to the output s of the memory cell, the output signal s of the cell being transferred at the output s_reg of the block through an internal module, this internal module operating according to modes able to modify the properties of the output signal of the PSC cell.

Advantageously, the output s_reg of the parametric test block forms for example the output of said parametric scan cell.

Several operating modes of the parametric test block are possible. In a normal operating mode, the output signal of the memory cell is, for example, transferred at the output of the block without modification. In other modes, a delay is applied to the output signal of the memory cell, to the slope or to the transient state, this delay possibly being infinite so that the output of the parametric test block displays the value previously present before the clock edge. In other modes, an amplitude modification is applied to the output signal of the memory cell. These modifications are, for example, performed by a module internal to the parametric test block.

In a variant embodiment, the parametric test block comprises for example a module for generating arbitrary signals, these signals being transferred to the output of the block. According to the preceding modes, modifications can be applied to the arbitrary signals, it being possible moreover for the latter to be provided by an outside generator.

The scan cell comprises for example at input a multiplexer whose output is linked to the input d of the memory cell, an input of the multiplexer receiving the test datum e_scan, the test datum e_scan being selected at the output of the multiplexer by a control input ctrl_NormTest.

A subject of the invention is also a digital integrated circuit comprising at least one parametric scan register such as previously defined.

Advantageously, this digital circuit comprises for example a controller generating signals for selecting the operating modes of the parametric test block.

A subject of the invention is also a method of testing a digital integrated circuit comprising scan registers including at least one scan register such as previously defined, the method comprising at least the following steps:
loading at least one test vector into the scan registers;
selecting an operating mode of the parametric test block equipping the scan register or registers (SC);
validating the operating mode so as to modify the input signal of the block before its propagation in the digital circuit;
analyzing the signal at the output of the path under test, the path under test being situated between the output s_reg and a primary or secondary output of the IC.

As an option it is possible to provide, as a function of the chosen test mode to provide a step of loading a sensitization vector so as to act on the switching of the parametric scan cells. Stated otherwise, the method furthermore comprises an additional step between the step of validating the operating mode and the step of analyzing the signal at the output of the path under test, this step consisting in loading a sensitization vector so as to act on the switching of the cell or cells forming a parametric scan register. A test vector is for example a binary word of n bits where n is the number of scan cells in the register.

Other characteristics and advantages of the invention will become apparent with the aid of the description which follows offered in relation to appended drawings which represent:

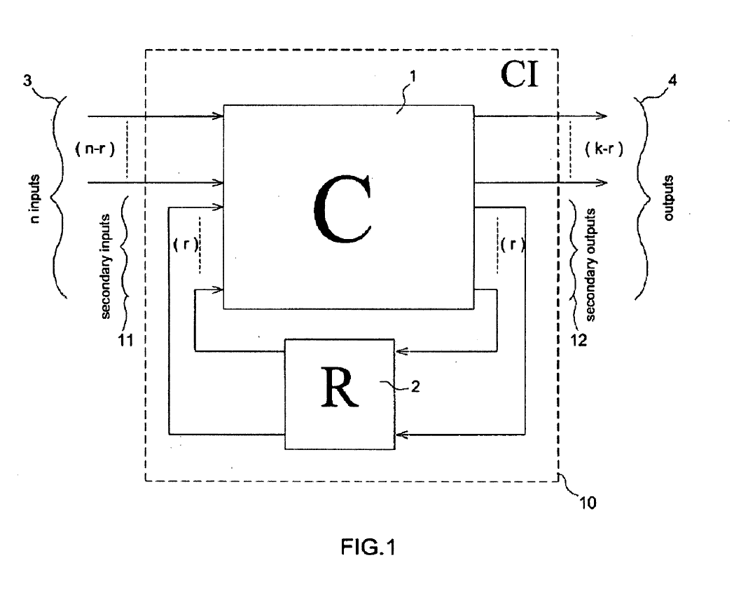

FIG. 1, an illustration of a generic model of a sequential digital IC;

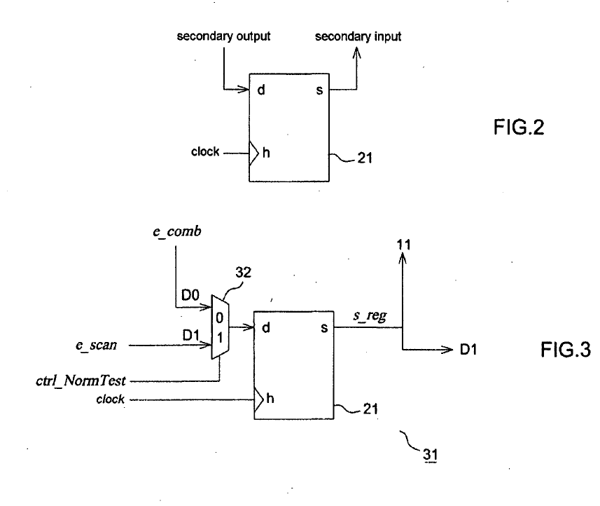

FIG. 2, a presentation through a basic diagram of a simple memory cell of a register;

FIG. 3, a presentation of a scan cell according to the prior art of a scan register;

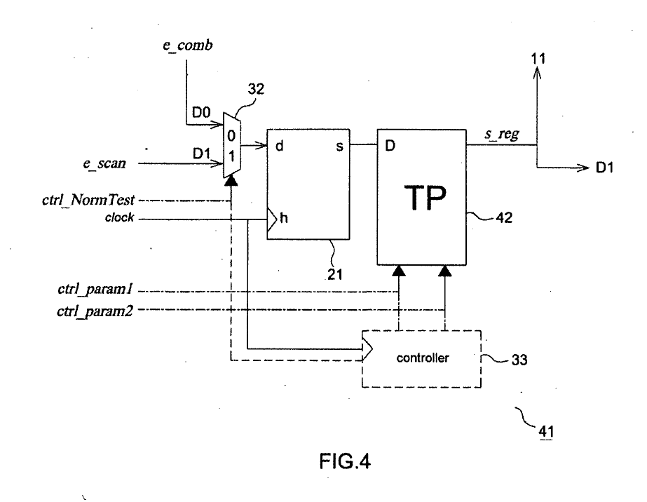

FIG. 4, a presentation of an exemplary parametric scan cell according to the invention;

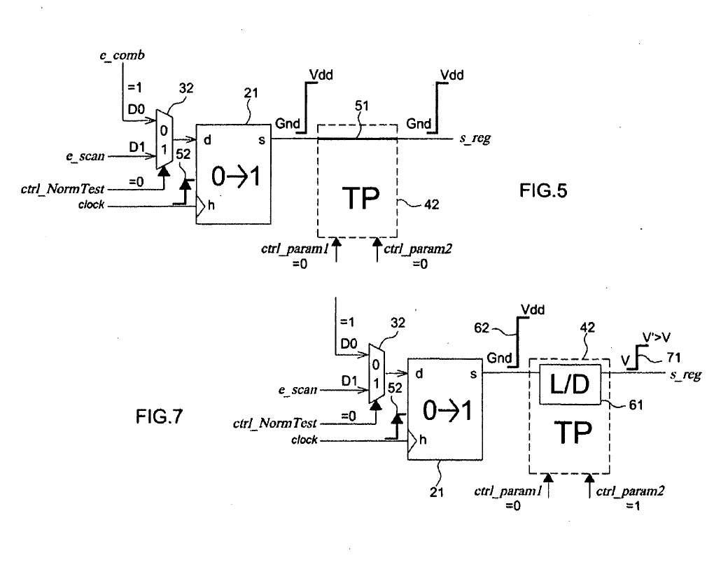

FIG. 5, an illustration of a first operating mode of a parametric scan cell according to the invention;

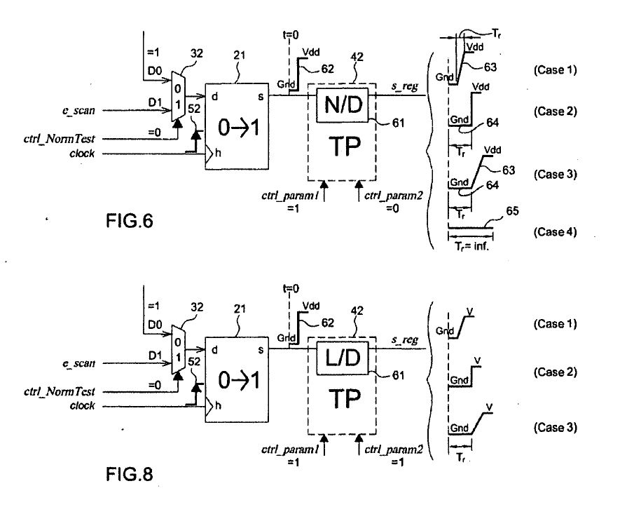

FIG. 6, an illustration of an operating mode applying delays;

FIG. 7, an illustration of an operating mode applying modifications of amplitude level;

FIG. 8, an illustration of an operating mode combining the two preceding modes;

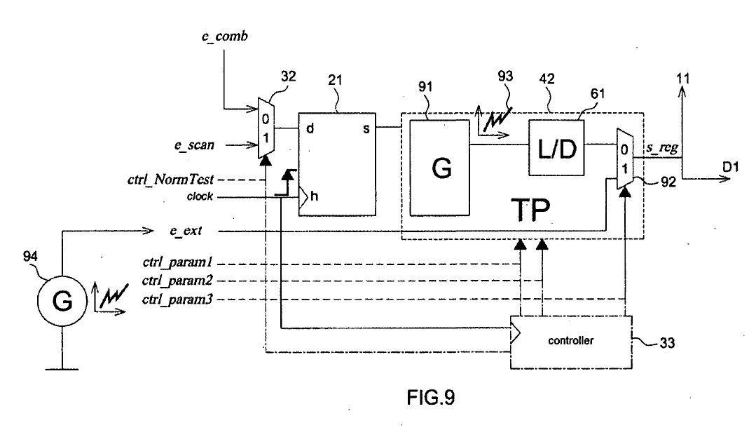

FIG. 9, another exemplary embodiment of a parametric scan cell according to the invention generating notably arbitrary signals;

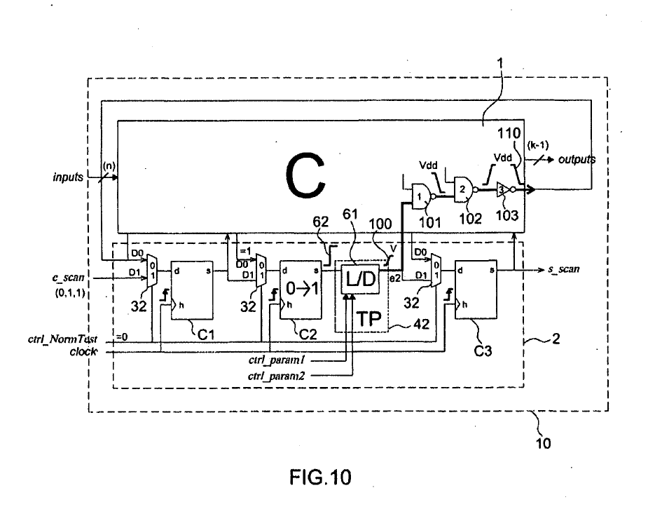

FIG. 10, an exemplary implementation of a parametric test method according to the invention;

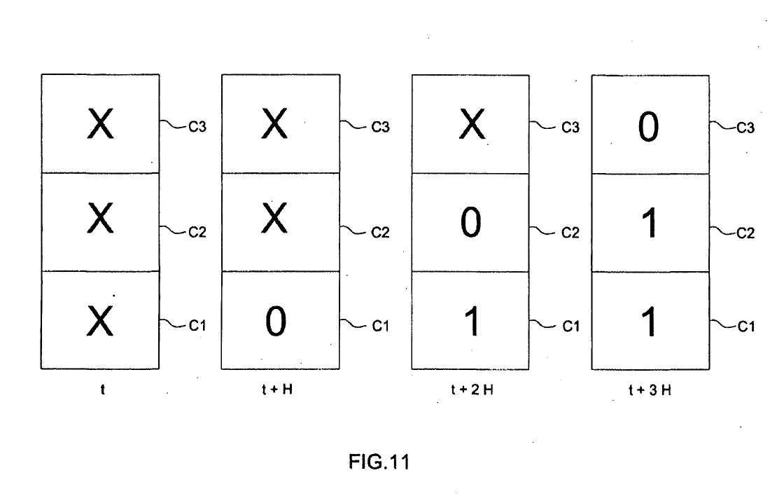

FIG. 11, a state of the scan cells contained in a register during the loading of a test vector;

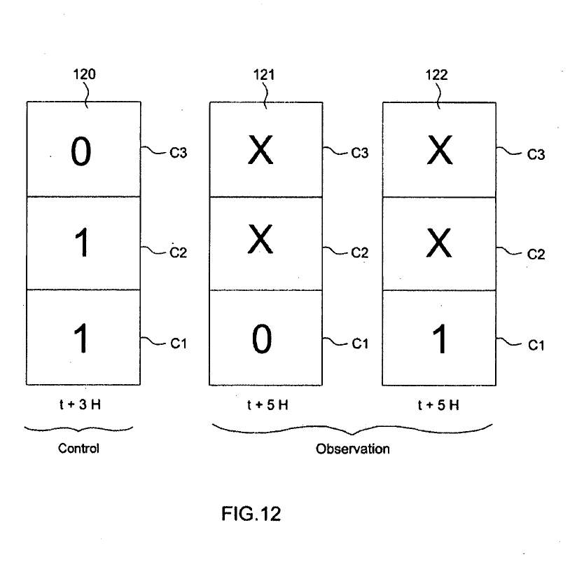

FIG. 12, an illustration of a test result, observed in the cells of the register of the aforesaid scan register.

FIG. 1 illustrates a generic model representing a digital IC 10. The function carried out by a digital IC can be represented in the form of a Moore or Mealy machine such as described notably in the document by E. F. Moore “Sequential Machines: Selected Papers”, Addison Wesley, Reading, Mass., 1964. In these two models, the IC is divided into two parts: a combinatorial part 1 and a register part 2. The combinatorial part can be represented by a logic function with n inputs 3 and k outputs 4. The register part 2 groups together r memory cells whose inputs, respectively outputs, are connected to r secondary outputs 12, or inputs 11, of the combinatorial part 1. More precisely, the r inputs of the register part 2 are linked to r secondary outputs out of the k outputs of the combinatorial part 1. Likewise, the r outputs of the register part 2 are linked to r secondary inputs out of the n inputs of the combinatorial part. It follows that r<n and r<k. The memory cells of the register part 2 contain the successive states of the IC.

FIG. 2 presents a basic diagram of a simple memory cell 21 with a data bit. Such a cell has a data input d, an output s allowing the reading of the memory and a clock synchronization signal input h. It is assumed that the writing of a datum in the cell 21 is performed on the rising edge of the clock signal. Writing could also be performed on the falling edge of the clock signal, or on its high and low levels. A chaining of simple memory cells 21 can be effected at the level of the register part 2. In particular, an input d of a cell 21 can be linked to a secondary output 12 and an output s of the cell can be linked to a secondary input 11.

FIG. 3 presents a conventional, simple, scan cell 31 according to the prior art. This cell 31 comprises a simple memory cell 21 of the type of that of FIG. 2 and a simple multiplexer 32 with 1 control bit. The output of the multiplexer 32 is connected to the data input d of the cell 21. A first data input D0 of the multiplexer is connected to a secondary output of the combinatorial part 1, denoted e_comb, and the other data input D1 is connected to the output of the adjacent memory cell, denoted e_scan. The thus chained cells form a scan register. The selection input for the multiplexer 32 is linked to an external input, denoted ctrl_NormTest. This additional input provided in an IC to be tested makes it possible notably to select the normal mode or the test mode of the scan register. In the normal mode, the input D0 is selected at the output of the multiplexer. In the scan mode, the input D1 is selected.

The output of the scan cell, which is also the output of the simple memory cell 21, denoted s_reg, is connected to a secondary input 11 of the combinatorial part and, if provision is made therefor, to the input D1 of the following scan cell. The scan cell 31 generates on its output s_reg conventional Boolean signals, type 0 and 1. Most prior art test techniques utilize Boolean test vectors. For this purpose they use scan memory cells of the type of that of FIG. 3 which make it possible, in test mode, to inject test vectors of Boolean values into the ICs. These techniques are aimed notably at minimizing the number of input points so as to reduce the number of tests which increases as 2ⁿ as a function of the number n of inputs tested.

FIG. 4 presents an exemplary parametric scan cell (PSC) according to the invention. This PSC 41 comprises notably a functionality which allows it to generate at output particular signals in addition to the conventional Boolean signals. For this purpose, the output s of the memory cell 21 is connected to a parametric test block 42. More particularly the output s is linked to a data input D of the parametric test block. The output of this block 42 constitutes the output r_reg of the PSC 41. This block 42 furthermore comprises at least one additional input for selecting parametric test modes. In the example of FIG. 4, the block 42 comprises two inputs for selecting modes.

The selection of four modes is ensured in the example of FIG. 4 by two control inputs ctrl_param1 and ctrl_param2. These control inputs are generated either from outside, or by an embedded controller 33, that is to say one that is installed in the IC for example. In the latter option, the selection input ctrl_NormTest of the multiplexer 32 could be also controlled by this embedded controller 33. The clock for synchronizing the memory cell 21 can also for example make it possible to synchronize the controller 33.

A PSC according to the invention such as illustrated by FIG. 4 possesses, like a conventional SC, a normal mode and a test mode with scan, denoted Test-Scan.
In the normal mode, the PSC is similar to a simple memory cell 21. The input D0 of the multiplexer is selected and the output s_reg of the PSC reproduces the output s of the memory register 21.
In the Test Scan mode, the memory cell is connected at output to the input of another memory cell, its input being connected to the output of an upstream cell. If the cell is the first of the chain then its input is linked to the e_scan input of the register. If the cell is the last of the chain then its output is connected to the output of the register. The memory cells 21 situated in one and the same chain share the same ctrl_NormTest signal. In this mode, the form, the amplitude and the delays of the output and input signals are determined by the technology used.

In addition to these two modes, a PSC according to the invention possesses a characterization mode, denoted Test-Characterization, implemented notably by the parametric test block 42. This mode makes it possible notably to apply signals that are non-conventional in an IC. This Test-Characterization mode itself comprises several modes. These modes are selected by the inputs ctrl_param1 and ctrl_param2 of the parametric test block 42. The following figures illustrate the various operating modes of this block 42, each of these modes corresponding to a mode of the Test-Characterization mode.

FIG. 5 illustrates a first operating mode of the parametric test block 42. In this first sub-mode, the Test-Characterization mode is disabled. The parametric test block 42 is then transparent, that is to say the output s of the memory cell 21 is linked directly to the output s-reg, by a direct link 51 for example. This mode is for example obtained when the two mode selection inputs ctrl_param1 and ctrl_param2 are both at the value 0. In the example of FIG. 5, it is assumed that initially the memory cell 21 contains the value 0 and a value 1, present at the input D0 of the multiplexer 32, is presented on its input d. At the clock rising edge 52 for example, the mode activated in the block 42 is validated in the memory cell and the output s switches from the value 0 to the value 1, in practice from a potential 0 to a potential Vdd for example, with a rise transition time assumed to be zero here. This example can be extended to the dual case where the output s goes from the 1 state to the 0 state.

In this mode where the parametric test block 42 is transparent, the PSC then operates according to one of the two modes: normal or Test-Scan, selected by the ctrl_NormTest input of the multiplexer 42. In the normal mode, the PSC operates as a simple memory cell. In the Test-Scan mode, the PSC operates as a conventional scan cell. FIG. 5 illustrates the case of the normal mode.

FIG. 6 illustrates another sub-mode of the Test-Characterization mode, called the Delay mode. The Delay mode, implemented by the parametric test block 42, is for example activated when the selection inputs ctrl_param1 and ctrl_param2 are respectively at 1 and at 0. In this mode, the output s of the memory cell 21 is connected to the input of a module 61 internal to the parametric test block 42. This internal module 61 will subsequently be called the “Level/Delay” module. The output of this module 61 is linked to the output s-reg of the block 42 forming the output of the PSC. This module applies delays to the incident signal 62, at the input thereof. This incident signal is the output signal s from the memory cell 21. The module 61 applies the delays according to one of the following four cases, illustrated notably by FIG. 6 for an exemplary incident signal of the rising step type:
Case 1: the “Level/Delay” module applies a delay to the slope of the incident signal by adding a delay Tr, for example a uniform delay 63, to the transition time, rising Tm or falling Td, of the incident signal 62. For example, the delayed rise time Tm′ at the output of the module 61 satisfies Tm′=Tm+Tr.
Case 2: the module applies a delay to the transient state e(t) of the incident signal 62, the transient state corresponding to the switch from a stabilized state, for example 0, to another stabilized state, for example 1. The transition times, or durations of the transient state, remain unchanged. The module adds a delay Tr, for example a uniform delay 64, to the incident signal. As a function of time, the output signal 62 of the module satisfies s(t)=e(t−Tr).
Case 3: this case is a combination of the previous two cases. A delay 63 is applied to the transition time and a delay 64 is applied to the transient state.
Case 4: this case corresponds to a disabling of the output. In this case, the delay applied 65 is infinite. The output s-reg of the block 42 does not switch and displays the value previously present before the clock rising edge 52.

FIG. 7 illustrates another sub-mode of the Test-Characterization mode, called the Level mode. This block is for example implemented by the internal “Level/Delay” module 61 of the parametric test block 42. The Delay mode is activated when the selection inputs ctrl_param1 and ctrl_param2 are for example respectively at 0 and at 1. The output s of the memory cell 21 is still linked to the module 61 and the output of this module is still linked to the output s-reg. In this mode, only the amplitudes of the incident signal 62 are modified by the “Level/Delay” module 61. Two types of amplitude modification can be applied:
A degradation of the potential Vdd, representing the value 1, to a potential V′ such that for example:

$$\frac{Vdd}{2} < {V}^{′} \leq Vdd \qquad ( 1 )$$

A degradation of the potential Gnd, representing the value 0, to a potential such that for example:

$$Gnd \leq V \leq \frac{Vdd}{2} \\ and {V}^{′} < V \qquad ( 2 )$$

In this Level mode, it should be noted that the module can act on the final value of the potential of the incident signal or on its initial value or on both values. FIG. 7 illustrates the principle described above in the case of an action on the initial and final values of the potential. The output signal of the memory cell which is the incident signal 62 of the “Level/Delay” module 61 is therefore modified at the level of the output s-reg into a signal 71 where the potential Gnd is replaced by the potential V and the potential Vdd is replaced by the level V′. In this case, the Level mode must be activated before capture of the value 0 present at the output of the memory register 21.

The “Level/Delay” module 61 can advantageously, effect the combination of the Delay mode and of the Level mode.

FIG. 8 illustrates another sub-mode of the Test-Characterization mode which is this combination of the Delay and Level modes. This mode is for example selected when the two selection inputs for the block 42 ctrl_param1 and ctrl_param2 are both in the 1 state. In this mode, the amplitudes and the delays of the incident signal 62 are modified as described previously in the Delay and Level modes. FIG. 8 illustrates a combination of the first three cases of FIG. 6 with a level modification where the potential Gnd switches to the potential level V such as defined in relation to FIG. 7.

FIG. 9 illustrates another example of embodiment of a PSR according to the invention. In this exemplary embodiment, the Test-Characterization mode possesses an additional sub-mode called Int/Ext, implemented by the parametric test block 42. To allow the realization of this Int/Ext mode, an additional selection signal ctrl_param3 is added. This signal, like the other two mode selection signals ctrl_param1 and ctrl_param2 can be provided from outside or by the embedded controller 33.

In this exemplary embodiment, the output s_reg of the PSC is linked either to an external input e_ext of the cell, or to a second internal module 91. The output s_reg is for example linked to the input e_ext when the signal ctrl_param3 is in the 0 state and linked to the second internal module 91 when ctrl_param3 is in the 1 state. For this purpose, the output of the second module 91 and the external input e_ext are for example connected to the inputs of an internal multiplexer 92 whose selection input is controlled by the signal ctrl_param3.

The function of the second module 91 is notably the generation of arbitrary signals 93, that is to say of signals other than signals of transition or step change type. In this type of module 91, the form, the amplitude and the delays of the signals to be generated are defined in an explicit manner. The outside signal e_ext is for example provided by an outside generator 94, the latter providing arbitrary signals.

The exemplary embodiment of FIG. 9 shows that the output of the second module 91 for generating arbitrary signals can pass through the first module 61 implementing the Level and Delay modes, thereby making it possible by altering the selection signals ctrl_param1, ctrl_param2, ctrl_param3 to combine the various modes, and notably to apply delays or level modifications to the random signals.

The parametric test block 42 can be embodied with the aid of transistors of MOS type, capacitors and resistors according to known techniques.

FIG. 10 illustrates a way of inserting a parametric scan register (PSR) according to the invention into the design flow of an IC 10, that is to say of defining a design technique for the IC with a view to parametric testing. A parametric test according to the invention can be used at the logic level. It exhibits notably the following characteristics:
It can be general or partial: the use of the parametric test does not necessarily involve the transformation of each scan register of the IC into a generalized PSR, or “Full-Scan” as it is known. The property of partial parametric scan, or pseudo-scan, signifies that only part of the memory cells of the scan register are modified into PSCs while the others remain unchanged. This property allows a compromise between the additional area and the effectiveness of the desired parametric test.
It is flexible: each PSC inserted into a register can operate differently. For example, a first PSC can be configured in the Delay mode while another PSC is configured in the external Ext/Int mode. This property offers several degrees of flexibility in terms of choices of parametric test. Each mode makes it possible to activate a particular mechanism for sensitizing the IC.
It possesses the property of modularity: each PSC can offer only a limited number of functionalities from among those previously described. For example, in the case of a PSR composed of two PSCs, the first PSC can include only the “Level/Delay” module 61 while the other PSC does not include this module but has an additional external input e_ext. It should be noted that a PSC might offer only the conventional scan function and no parametric test function. The latter property also makes it possible to limit the additional area added to the IC by the test circuits.

The number of PSCs to be inserted into an IC, and more precisely into each scan register, the choice and the selection of the modes of each PSC are notably determined by the nature of the function, the structure and the specifications of the IC to be tested.

The example of the IC 10 of FIG. 10 illustrates a possible manner of operation of the parametric test. The IC comprises a combinatorial part 1 and a register part 2 forming a parametric scan register (PSR). This register comprises three memory cells C1, C2, C3 of the type of that 21 illustrated by the previous figures. Among these cells, a single one C2, is equipped with a parametric test block 42 to form a PSC. The other cells C1, C3 include only the conventional scan function, while being equipped with a multiplexer 32 with an e_scan input. All these cells C1, C2, C3 are chained in test scan mode.

In the block 42 equipping the cell C2, only the “Level/Delay” module 61 is present. In this example, this module 61 makes it possible notably to characterize the sensitivity of a functional path between an input e2 and an output o2, integrated into the combinatorial part 1, during the production test phase. This path passes for example through several logic gates 101, 102, 103. A signal present at e2 drives a first gate 101, the signal being provided as output from the “Level-Delay” module 61 and therefore as output from the parametric test block 42 of the PSR. This signal e2 additionally drives the input of the multiplexer 32 of the following cell C3 in the chain.

This characterization consists for example in propagating signals of transition or step change type with particular properties such as delays or changes of level. By way of example, the desired characterization consists in generating a rising transition, with a final amplitude V and an initial amplitude Gnd, a rise transition time Tm and a uniform delay Tr on the incident signal 62 exiting the cell C2 and entering the “Level/Delay” module 61.

In a first step, the test vector is loaded into the PSR register 2, formed by chaining the three cells C1, C2, C3 through the e_scan input. The test vector is (0, 1, 1). The loading is performed in series by activating the Test-Scan mode. In this case, the signal ctrl_NormTest being for example at 0, the multiplexers 32 of the memory cells select the input D1. The input D1 of the first cell C1 of the chain is linked to the e_scan input, then the other inputs D1 of the other cells C2, C3 are connected to the outputs of the other cells C1, C2 to form the complete chained register 2. For the record, in normal mode, the signal ctrl_NormTest being for example at 1, the inputs of the cells C1, C2, C3 are linked to the inputs D0 of the multiplexers 32 which are themselves linked to the combinatorial part as described in relation to FIG. 1.

FIG. 11 illustrates the state of the PSR register 2, and more particularly the state of the scan cells C1, C2, C3 at an instant t, and at subsequent instants dependent on the clock edges. At the instant t, the scan cells C1, C2, C3 are in an indeterminate state X. At the following clock edges, defining instants incremented by the time interval H, the states are:
at t+H, the cells C1, C2, C3 are respectively at 0, X, X;
at t+2H, the cells C1, C2, C3 are respectively at 1, 0, X;
at t+3H, the cells C1, C2, C3 are respectively at 1, 1, 0;

Returning to FIG. 10, at the instant t+3H, the test vector is completely loaded. The generation of a step change 62 on the output of the PSC cell C2 requires the application of the value 1 to its input. This step change is necessary to characterize the path e2-o2. In the example of FIG. 6, the step change is generated via the Test-Scan mode by shifting towards the cell C2 the value 1, contained in the cell C1 at t+2H. Thus, at t+3H, the cell C2 captures a value 1 on its input. The parametric tests are subsequently applied to the output signal from the cell C2, the signal modified by the “Level/Delay” module 61 being subsequently injected into the path e2-o2. In order that the block 42 equipping the cell C2 is in the proper operating mode at the instant t+3H, the Test-Characterization mode is for example activated in the block 42, more particularly in the “Level/Delay” internal module 61, at the instant t+2H, by placing the selection signals ctrl_param1 and ctrl_param2 in the 1 state. Thus, at t+3H, the mode is validated in the block 42 and a rising step change 62 is present on the input of this block. The characterization procedure therefore starts at this instant. For the given inputs ctrl_param1 and ctrl_param2, the Delay and Level modes of the block 42 are selected. The values V, Tm and Tr to be applied to the incident signal 62 are stored in the internal module 61. On the output s_reg of the PSC, there then appears a signal of rising transition type 100 with the parameters V, Tm and Tr forming the signal present at the input e2.

The signal at e2 having traveled for example through three signal inversion gates 101, 102, 103 up to the output o2, a falling edge 110 appears at this output, having a full-scale amplitude Vdd and delayed by a time T₀ with respect to the source signal 62 at the output of the cell C2. The amplitude Vdd depends on the output gate 103 at o2. The delay T₀ is due to the aggregate of the delays Σtᵢ=ΔT of the path characterized e2-o2 and to the delays t_{V}, t_{Tm}, t_{Tr} generated by the “Level/Delay” module 61, ΔT being the normal delay of the path with no defect. The delays t_{V}, t_{Tm}, t_{Tr} are respectively generated by applying the amplitude V and the delays Tm and Tr to the incident signal 62, these parameters V, Tm and Tr having been defined when presenting the various sub-modes of the Test-Characterization mode. The delay T₀ is notably defined by the following relation:

T₀=Σtᵢ+t_{V}+t_{Tm}+t_{Tr} (3)

To observe the result of the test, the output o2 is connected to the input D0 of the multiplexer 32 of the cell C1, this input having been selected previously by the signal ctrl_NormTest.

After the time ΔT, the cell C1 captures the value 0 present at the output o2 if the IC is intact. On the other hand, if the signal propagated on the path e2-o2 reveals that a defect is present and that this defect produces a degradation in the final amplitude of the signal at output o2 and/or adds an additional delay, then the cell C1 captures an erroneous value, or logic error, that is to say a 1 value instead of the expected 0 value.

FIG. 12 illustrates the observation of the result of the test performed on a circuit of the type of FIG. 10, in a case with no defect and in a case with a defect. In a control phase, at t+3H, the cell C2 is in the 1 state, the set of cells 120 reproducing the test vector (0, 1, 1). As described previously the corresponding signal at output will travel up to the output o2. In the observation phase, the state of the cell C1 that captured the value at output o2 at an instant T_{OBS}=t+3H+ΔT is polled. In the case 121 where the IC is intact, the cell C1 contains the value 0, the other cells C2, C3 having for example an indeterminate value X. In the case 122 where the IC exhibits a defect on the path e2-o2, the cell C1 contains the value 1.

A combination of characterization is possible in the IC, notably under the assumption that other PSCs might be present therein. Supposing for example that the cell C3 is also in the PSC configuration and that a dependence exists between the second gate 102, traversed by the path e2-o2 and the output of the cell C3, two types of particular signals can then combine in this gate 102 and propagate on the part which is downstream of the path e2-o2.

1. A parametric scan register comprising:
a scan cell comprising:
at least one data input able to receive a test datum;
an output responsive to a synchronization signal, to produce an output signal indicative of the test datum; and
a parametric test block having an input linked to the output of the scan cell,
wherein the output signal of the scan cell is transferred to an output of the parametric test block through an internal module having a plurality of operating modes, at least one mode able to modify the output signal of the scan cell.

2. The register as claimed in claim 1, wherein the output of the parametric test block forms the output of the scan cell.

3. The register as claimed in claim 1, wherein an operating mode transfers the output signal of the scan cell to the output of the parametric test block without modification.

4. The register as claimed in claim 1, wherein in an operating mode, the internal module applies a delay to the output signal of the scan cell.

5. The register as claimed in claim 1, wherein in an operating mode the internal module applies a delay to the transient state of the output signal of the scan cell.

6. The register as claimed in claim 1, wherein in an operating mode the internal module applies an infinite delay to the output signal of the scan cell.

7. The register as claimed in claim 1, wherein in an operating mode the internal module applies an amplitude modification of the output signal of the scan cell.

8. The register as claimed in claim 1, wherein the parametric test block comprises a module for generating arbitrary signals, said arbitrary signals being transferred to the output of the parametric test block.

9. The register as claimed in claim 8, wherein the arbitrary signals generated by the module are transferred to the output of the parametric test block through the internal module.

10. The register as claimed in claim 8, wherein the output of the parametric test block is provided by the output of a multiplexer, wherein an input of the multiplexer receives an arbitrary signal generated by an external generator.

11. The register as claimed in claim 1, further comprising a multiplexer having an output that is linked to the input of the scan cell, an input of the multiplexer receiving the test datum (e_scan), the test datum being selected at the output of the multiplexer by use of a control input.

12. A digital integrated circuit, having at least one parametric scan register comprising:
a scan cell comprising:
at least one data input able to receive a test datum;
an output responsive to a synchronization signal, to produce an output signal indicative of the test datum; and
a parametric test block having an input linked to the output of the scan cell,
wherein the output signal of the scan cell is transferred to an output of the parametric test block through an internal module having a plurality of operating modes, at least one mode able to modify the output signal of the scan cell.

13. The digital integrated circuit as claimed in claim 12, further comprising a controller to generate signals that select the operating modes of the parametric test block.

14. The digital integrated circuit as claimed in claim 13, wherein the controller generates a control signal for the input multiplexer.

15. A method of testing a digital integrated circuit, said circuit comprising scan cells at least one scan cell of which forms a parametric scan register, said scan cell comprising:
at least one data input able to receive a test datum;
an output responsive to a synchronization signal, to produce an output signal indicative of the test datum; and
a parametric test block having an input linked to the output of the scan cell,
wherein the output signal of the scan cell is transferred to an output of the parametric test block through an internal module having a plurality of operating modes, at least one mode able to modify the output signal of the scan cell
wherein the method comprises the following steps:
loading at least one test vector into the scan cells, the test vector corresponding to a path under test;
selecting an operating mode of the parametric test block;
validating the operating mode in order to modify the input signal of the parametric test block before its propagation in the digital circuit; and
analyzing the signal at the output of the path under test.

16. The test method as claimed in claim 15, further comprising, after the step of validating the operating mode and before the step of analyzing the signal at the output of the path under test, an additional step of loading a sensitization vector in order to act on the switching of the one or more scan cells forming a parametric scan register.
